(19) United States
(12) Patent Application Publication
(10) Pub. No.: US 2003/0103021 A1
(43) Pub. Date: Jun. 5, 2003

(54) Display device

(75) Inventors: Nigel D. Young, Redhill (GB); Mark T. Johnson, Veldhoven (NL)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 10/307,697

(22) Filed: Dec. 2, 2002

(30) Foreign Application Priority Data
Dec. 5, 2001 (GB) 0129068.3

(51) Int. Cl. G09G 3/30

(52) U.S. Cl. 345/76

(57) ABSTRACT

A display device comprises an array of display pixels, each pixel comprising a first and second display elements (12, 14). The first element I(12) s drivable between at least two transmission states, for example an LC cell. The first display element (12) overlyies the second display element (14) which is an electroluminescent display element. The first display element (12) can be used when the ambient light conditions are sufficient, and enables an electroluminescent (EL) element to be used when the light conditions are not sufficient. By providing the display element over each other, the resolution of each is not impaired. The first display element (12) can then be driven to a transparent state when using the EL element beneath.

The invention relates to display devices, particularly to reflective pixellated display devices.

Reflective active matrix displays are well known and different types of reflective display are known. Early designs essentially used a transmissive display arrangement with a reflector at one side. Thus, polarizers were provided on both sides of the LC material. These provided poor image quality, and a preferred arrangement uses a single linear polarizer to polarize light at the input of the liquid crystal layer. After modulation of the state of polarization through the liquid crystal layer, the light ray is passed to a colour filter beneath the LC material before reflection for a second pass through the material.

Reflective displays are also known using circular polarizers. This requires a more complicated arrangement of polarizers and quarter wave plates.

Reflective displays have the significant advantage of low power consumption, but they can of course only be viewed when there is sufficient ambient light. One solution to this problem is to provide a front or back light for operation in dark conditions. This form of lighting gives rise to deteriorated image quality and increased power consumption. In particular, frontlighting can affect the brightness and contrast of the displayed image, especially when the display is being used in its reflective mode.

Matrix display devices employing electroluminescent, light-emitting, display elements are also well known. The display elements may comprise organic thin film electroluminescent elements, for example using organic materials, or else light emitting diodes (LEDs) using traditional III-V semiconductor compounds. Recent developments in organic electroluminescent materials, particularly polymer materials, have demonstrated their ability to be used practically for video display devices. These materials typically comprise one or more layers of a semiconducting conjugated polymer sandwiched between a pair of electrodes, one of which is transparent and the other of which is of a material suitable for injecting holes or electrons into the polymer layer. An example of such is described in an article by D. Braun and A. J. Heeger in Applied Physics Letters 58(18) p.p. 1982-1984 (May 6, 1991).

The organic material can be fabricated using a PVD process, by a spin coating technique using a solution of a soluble conjugated polymer, or by printing for example inkjet printing.

Organic electroluminescent materials exhibit diode-like I-V properties, so that they are capable of providing both a display function and a switching function, and can therefore be used in passive type displays. Alternatively, these materials may be used for active matrix display devices, with each pixel comprising a display element and a switching device for controlling the current through the display element.

These devices have higher power consumption than reflective LC and may therefore not be efficient for use when the ambient light conditions are good.

According to a first aspect of the invention, there is provided a display device comprising an array of display pixels, each pixel comprising a first display element which is drivable between at least two transmission states, the first display element overlying an electroluminescent display element.

This arrangement enables a first display element to be used when the ambient light conditions are sufficient, and enables an electroluminescent (EL) element to be used when the light conditions are not sufficient. By providing the first display element over the EL element, the resolution of each is not impaired. The first display element can then be driven to a transparent state when using the EL element.

The electroluminescent display element may comprise an organic material (for example a polymer) sandwiched between two electrodes and the material comprises a layer shared between all electroluminescent display elements, the layer being colour patterned so that different electrolumiescent display elements have different colours.

In this way, the first display element can be a grey scale display element, and colour filtering is provided by the EL element, so that the colour filtering operation is shared between the two types of display device.

The first display device can take a number of forms, providing it can be driven to a transparent state to allow operation of the EL display element. For example, the first display element may comprise an electrophoretic, electrowetting, electrochromic or phase change material display element.

In a preferred embodiment, the first display element comprises a liquid crystal element. This may take the form of an IPS (in-plane switching) display element having a planar electrode structure having two or more interlocking electrodes. One of the electrodes of the EL display element can then comprise the planar electrode structure.

In an alternative version, the liquid crystal display element comprises liquid crystal material sandwiched between transmissive first and second electrodes, and the electroluminescent display element comprises an organic material sandwiched between third and fourth electrodes, the second and third electrodes being at the junction of the liquid crystal display element and the electroluminescent display element. These second and third electrodes are preferably formed from transparent ITO.

A single shared layer may define the second and third electrodes, so that one of the control signals is shared between the EL and LC elements. Alternatively, they may be separate and may have a substantially transparent insulating (dielectric) layer between them. This enables the drive voltages to the LC and EL elements to be independent.

The fourth electrode is preferably an opaque conducting layer for example a metal layer, and acts as the reflecting surface for the LC element. In this way, one of the electrodes of the EL element has a dual function, acting also as the reflecting plate of the LC element.

Each pixel may comprise a pixel drive circuit which operates in first and second modes, wherein in the first mode the first display element is turned off thereby to render the first display element transparent and the electroluminescent display element is controlled, and in a second mode the electroluminescent display element is turned off and the first display element is controlled.

The transparency of the LC element when turned off allows the EL element to function, and the EL element when turned off can act as a colour filter for the LC pixel, as mentioned above.

A third mode may also be provided in which both the first display element and the EL element are operated, so as to provide extra light for reading the display. The EL pixels can be turned on with constant intensity and used as a backlight.

The pixel drive circuit may comprise:

a first connection connecting the first electrode to a reference voltage;

an address transistor for addressing the pixel, thereby allowing a data signal to pass to the remainder of the pixel; and

a mode selection section which in a first mode connects the second electrode to a fixed potential and couples an input signal to the fourth electrode, and which in a second mode couples an input signal to the second electrode and isolates the fourth electrode from the input signal.

In the first mode, both electrodes in the LC cell are grounded, and the data signal drives the EL display. In the second mode, the input signal is isolated from the EL drive electrode (the fourth electrode) and the LC element is controlled at the second electrode.

The mode selection section may in a third mode connect both electrodes simultaneously to a respective input signal.

Each pixel drive circuit may further comprise a current source driven by the data signal, and wherein the mode selection section comprises a first transistor coupled between the second electrode and a fixed potential, a second transistor coupled between the address transistor and the second electrode and a third transistor coupled between the current source and the fourth electrode, wherein in the first mode the first and third transistors are turned on and the second transistor is turned off, and in the second mode the first and third transistors are turned off and the second transistor is turned on.

This provides the required current-addressing of the EL display elements. In a third mode, all transistors are turned on.

In an alternative drive circuit, there is provided:

a first connection connecting the first electrode to a reference voltage;

an address transistor for addressing the pixel, thereby allowing a data signal to pass to the remainder of the pixel;

a current source for converting the data signal to a current and applying the current to the second and third electrodes;

wherein for data signals in a first range, the current is used to address the electroluminescent element and for data signals in a second range a voltage is applied to the fourth terminal to turn off the electroluminescent element and the current is used to address the liquid crystal element.

This arrangement using current addressing of both the EL and LC elements and can give a simplified circuit.

Embodiments of display devices in accordance with the invention will now be described, by way of example, with reference to the accompanying drawings, in which:

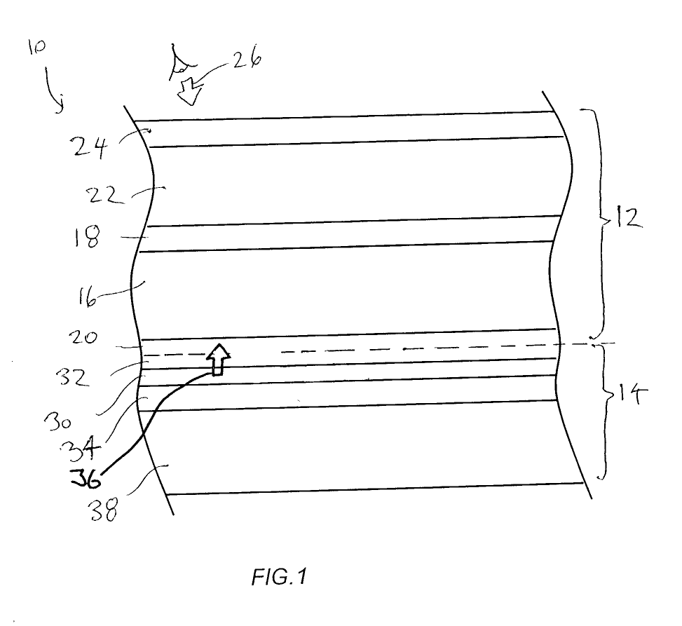

FIG. 1 shows the structure of the display device of the invention;

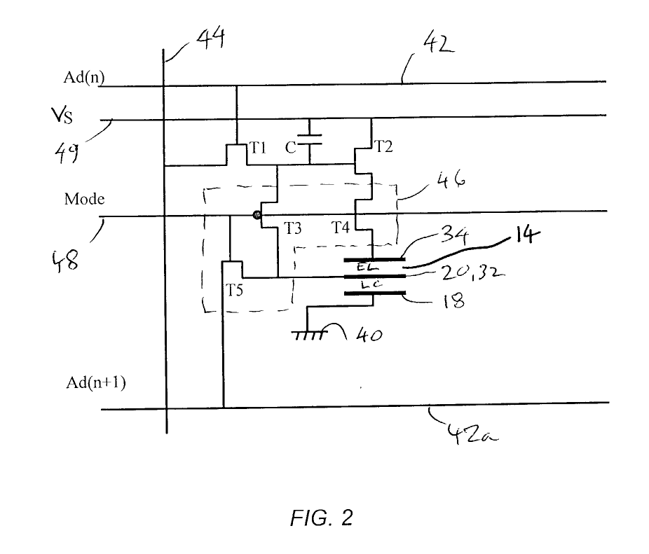

FIG. 2 shows in simple form the equivalent circuit of a first example of pixel circuit in the display device of FIG. 1;

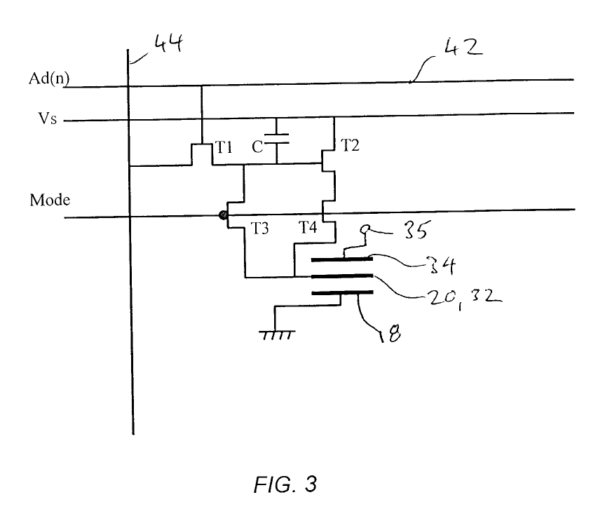

FIG. 3 shows in simple form the equivalent circuit of a second example of pixel circuit;

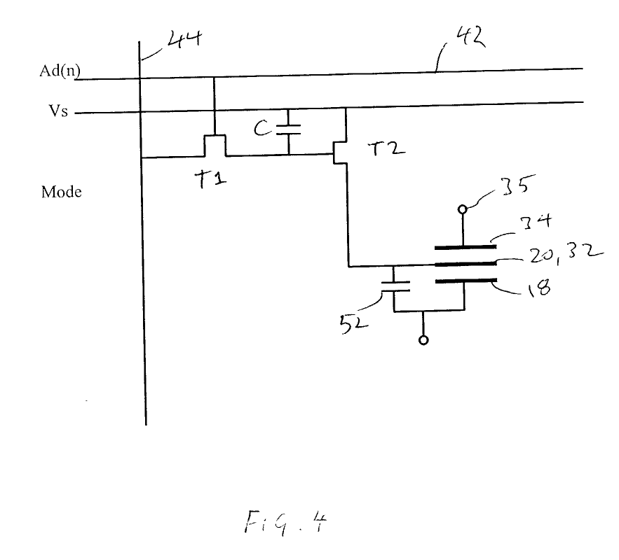

FIG. 4 shows in simple form the equivalent circuit of a third example of pixel circuit.

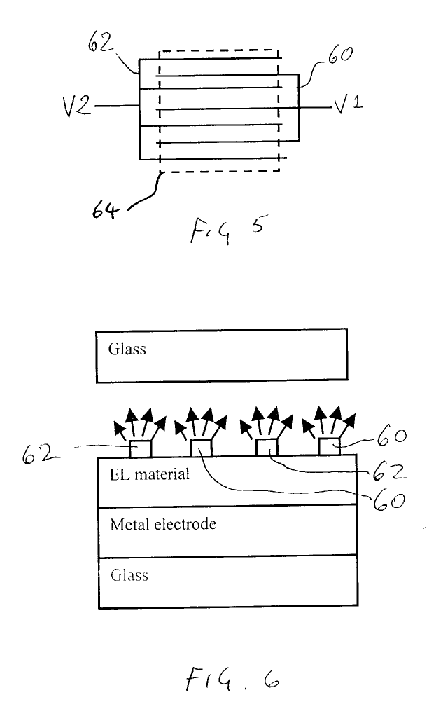

FIG. 5 shows an alternative type of liquid crystal display element; and

FIG. 6 shows the combined display using the LC element of FIG. 5.

The invention provides a combination of a first display element with an EL display element, to provide various advantages. One specific example in which a reflective LC display element overlies an organic EL display element is described below. There are other types of display element which may be used as the first display element, and this will be elaborated after the specific example.

FIG. 1 shows the structure of a display device of the invention. The display device 10 comprises an array of pixels defined by a multiple layer structure. Each pixel includes a reflective liquid crystal (LC) display element 12 and an electroluminescent (EL) display element 14. As shown in FIG. 1, the LC element comprises liquid crystal material 16 sandwiched between first and second electrodes 18, 20. This LC stack 16, 18, 20 is provided on one side of a glass substrate 22, and a polarizer 24 is provided on the opposite side of the substrate 22. These layers define a known reflective LC display configuration, and an additional reflective layer is required beneath the second electrode 20. The display pixel is viewed from above, as represented by arrow 26. In addition to the polarizer 24, other films can be applied for the purposes of antireflection, scattering, LC compensation or colour correction.

The EL display element 14 comprises an organic material 30, in a preferred example a polymer layer, sandwiched between third and fourth electrodes 32, 34. The second and third electrodes 20, 32 may be defined as a single conducting layer, as shown in FIG. 1, or they may be formed separately. In each case, the second and third electrodes 20, 32 define the junction between the reflective LC element 12 and the EL element 14.

The EL display element is arranged to emit light upwardly, as represented by arrow 36. For this purpose, the top electrode (the third electrode 32) is required to be transparent, and is therefore formed from ITO. The electrodes 18, 20 adjacent to the LC material 16 are also transparent, and again preferably formed from ITO. The fourth electrode 34 is a metal opaque layer, and as will be known by those skilled in the art the operation of the EL element requires this electrode to be a low work function material and with high reflectivity.

The layers 30, 32, 34 of the EL display element 14 are provided on one side of a glass substrate 38 and as will be known by those skilled in the art the display element has diode-like electrical properties.

By providing both EL and LC display elements within a single display device, it is possible to benefit from the low power consumption of reflective displays when ambient light conditions are sufficient, but still to provide a display function using the EL display elements when light conditions are poor. The specific structure of FIG. 1 provides various advantages relating to the quality of the displayed image as well as minimising the cost of manufacturing the combined display device.

As mentioned above, the reflective LC display element requires a reflective surface beneath the LC stack 16, 18, 20. In the structure of FIG. 1, this reflective surface is provided by the fourth electrode 34, which therefore forms part of the LC and EL element structure. When the display is being driven in LC mode, the LC material is modulated using the first and second electrodes 18, 20 and the metal fourth electrode 34 is biased to turn off the EL element. In view of the diode-like electrical properties of the EL display element, this can be achieved by ensuring a reverse bias across the EL element.

Additionally, the EL polymer layer 30 can be used to act as a colour filter for the LC display element 12. In particular, in order to implement a colour EL display, the organic layer 30 is patterned to provide a coloured pixellated structure. This colouring may be achieved either by using different polymers, or else by dying a single polymer layer, for example using printing techniques. For organic LED devices, there are known techniques for defining different colour pixels, for example shadow mask evaporation or inkjet printing.

In each case, the coloured patterned polymer layer 30 acts as a transmissive filter when the EL display element is turned off. In this way, the polymer layer 30 acts both as a filter for the LC display element as well as providing the electroluminescence for the EL element.

In the structure of FIG. 1, the LC material layer 16 and the polymer material layer 30 are provided as continuous layers across the entire display area. As is conventional, the pixellated structure of the display is defined by an array of pixel address circuits. There are various different ways of addressing the structure shown in FIG. 1, and a number of different possible alternatives will be discussed below.

In each of the schemes envisaged below, the LC display pixels are independently addressable by means of the second electrode 20. Thus, in each case the first electrode 18 is shared between all pixels, or at least a large number of pixels, whereas the second electrode 20 is patterned to define an independently addressable pixel electrode for each LC display pixel. This pixellation of the second electrode layer can also be used to enable independent EL drive signals to be applied to different pixels, although it may additionally be beneficial to pixellate the metal fourth electrode 34.

Since the light is emitted upwardly (arrow 36) the components of the pixel drive circuitry can be formed beneath the fourth electrode 34 without interfering with the passage of light. The required connections from the pixel circuitry to the individual electrodes defined by the metal fourth electrode 34 and/or the second and third electrodes 20, 32 will then be implemented using vias where required.

FIG. 2 shows a first pixel circuit in which the driving of the LC element and the EL element are kept as separate as possible. This enables voltage addressing of the LC display elements and current addressing of the EL display elements.

In the circuit of FIG. 2, the first LC electrode 18 for all pixels of the display is connected to ground 40. The second and third electrodes 20, 32 are defined as a single layer, and this layer is patterned to define individual electrodes for each pixel. The circuit of FIG. 2 is provided for each pixel of the display, and as mentioned above the components in the circuit of FIG. 2 are provided beneath the fourth electrode 34. The circuit essentially comprises a number of transistors and capacitors, and these are arranged as thin film components defined by a multiple layer structure over the glass substrate 38.

The pixels are arranged in rows and columns with each row of pixels sharing a column row address line 42 and each column of pixels sharing a common data signal line 44. By providing a suitable row pulse on the address line 42, an address transistor T1 is turned on to allow the data signal from the data signal line 44 to pass to the remainder of the pixel circuit. The data signal can then be used in two ways. A first use of the data signal is to drive a current source by applying a voltage to the gate of a current source transistor T2, this gate voltage depending upon the data signal level. The voltage on the gate is held by a storage capacitor C. The resulting current flowing through the current source transistor T2 is supplied to the fourth electrode 34 through an isolating transistor T4. In a second mode, the voltage on the data signal line 44 is supplied to the second electrode 20, in order to drive the LC display element to the required voltage.

In order to control the operation of the drive circuit in these two modes, a mode selection section 46 is provided. This mode selection section 46 comprises a third transistor T3 which allows or prevents the data signal from the addressing transistor T1 to be provided to the second electrode 20. A fourth transistor, the isolating transistor T4, allows or prevents the output of the current source transistor T2 to be provided to the EL display element 14, and a fifth transistor T5 selectively couples the third electrode 32 to the addressing line 42a of the next row of pixels.

The mode selection section 46 is controlled by a mode selection line 48. In a first mode, the transistor T5 is turned on so that the second electrode 20 is coupled to the address line 42a. As the next row of pixels is not currently being addressed, there is zero volts on the address line 42a, so that the operation of transistor T5 is to apply the same voltage to the second electrode 20 as is present on the first electrode 18. In this way, the LC cell is turned off, and is transparent. The third transistor T3 is turned off, thereby isolating the data signal at the output of the addressing transistor T1 from the LC display element. The isolating transistor T4 is turned on so that the current provided by the current source transistor T2 is supplied to the fourth electrode 34, in order to drive the EL display element.

In the second mode, the third transistor T3 is turned on so that the data signal at the output of the addressing transistor T1 is supplied to the second electrode 20, and can therefore be used to drive the LC display element. The isolating transistor T4 is turned off so that the current source transistor T2 is isolated from the EL display element. The fourth electrode 34 is effectively floating so that there is no voltage across the EL polymer layer 30 and no current can flow through it. The fifth transistor T5 is also turned off. In this mode, the LC display element is driven and the polymer layer 30 of the EL display element functions as a colour filter.

In the second mode, it is additionally possible to switch off the voltage supply 49 to the current source transistor T2. This saves power.

In this circuit configuration, two modes of operation are both addressed through a single addressing transistor T1, and use a common storage capacitor C both for the current source operation and for storing the data signal voltage in the LC mode of operation.

The implementation requires the EL display to emit light away from the substrate 38. Conventional implementations of EL displays provide emission of light through the substrate, but EL displays emitting light away from the substrate are now being implemented.

In the pixel configuration of FIG. 2, the EL display drive current is provided to the fourth electrode 34. This requires the fourth electrode 34 to be patterned to define individual pixel electrodes.

In an alternative arrangement, the pixel drive signals for both the EL and LC display elements can be supplied to the intermediate electrodes 20, 32. In particular, the LC display element will remain transparent provided there is a voltage across the LC material below the threshold voltage of the LC material. This threshold voltage may typically provide a 4V swing, and this is sufficient to drive the EL display elements.

FIG. 3 shows a pixel circuit which is a modification of the circuit of FIG. 2 and which enables the drive signal to be provided to the central electrode 20, 32.

In the LC mode of operation, the current source transistor T2 is again isolated from the central electrode 20, 32, but in the EL mode, the central electrode 20, 32 is no longer coupled to the next addressing line. This eliminates the need for transistor T5 in FIG. 2 and avoids the need for the pixel circuit to connect to a different addressing line. Instead, a sufficiently low voltage is required on the electrode 20, 32 that the LC material will remain transmissive. The metal electrode 34 is coupled to a voltage source 35, and when in LC mode, the voltage on supply 35 is selected to reverse bias the EL element.

The pixel drive circuit can be simplified further, again taking advantage of using the intermediate electrodes for providing signals to both the EL and LC display elements. FIG. 4 shows a pixel address circuit in which the LC display element is also addressed using a charge addressing scheme. As shown, a single addressing transistor T1 is again used and which drives a current source transistor T2. The current from the current source is provided to the central electrode 20, 32. When operating in EL mode, the current provided drives the intermediate electrode, and the first and fourth electrodes 18, 34 are held at fixed potentials. The voltage resulting on the intermediate electrode 20, 32 during this drive scheme is not sufficient to overcome the threshold voltage of the LC material so that it remains transmissive.

When operating in the LC mode, the reference voltage on the EL terminal 35 is changed so that the EL display device will be reverse biased. The current provided by the current source transistor T2 is converted to a voltage by the storage capacitor 52, and this voltage results in driving of the LC display element, in conventional manner.

In order to ensure the desired voltage is provided across the LC cell, a reset scheme may be required to reset the LC material to a reference voltage before addressing the pixel. This can be achieved by providing an extra thin film transistor to connect the second electrode 20 to an additional reference voltage line.

The LC capacitance changes with voltage, so that the grey level for a given amount of charge depends upon the previous grey level (since the LC will not switch in a short time). To overcome this inaccuracy, a large storage capacitor 52 should be used, or else the reset operation should be carried out sufficiently early to allow the liquid crystal cell to switch to a predetermined state before applying the data signal. Preferably, the cell should be reset to a black state, which is the change to the LC cell which can be implemented most rapidly.

As an alternative, the current provided to the LC cell can be controlled more accurately to take into account the previous grey scale level of the LC cell. This approach requires a frame store, but it is already increasingly common for display devices to be provided with frame stores for other reasons.

The pixel circuits described above each have as signal input a voltage on a data signal line, and in each case this voltage is used to drive a current source for the purpose of addressing the EL display element. However, a current signal may equally be provided on the data signal line, which will of course require a different pixel circuit implementation and will require different column driver circuitry. However, addressing EL display devices using current signals is a well known approach which will be apparent to those skilled in the art. The use of a current data signal to drive an LC display requires additional measures to ensure the correct voltage across the LC cell results, as discussed above in connection with FIG. 4.

In the examples above a reflective LC display element is employed in which liquid crystal material is sandwiched between facing electrodes. Another possible reflective LC cell uses the so-called “In-Plane Switching” (IPS) effect. The two electrodes are made in the form of interlocking comb shapes formed on the same substrate, as shown in FIG. 5. The electrodes 60, 62 are provided with different voltages V1, V2, and the pixel area is shown as 64.

If this electrode pattern is used as one of the electrodes for the underlying EL display element, only the part of the EL layer covered by the electrode structure 60,62 will emit light, as shown in FIG. 6. However, the local intensity of the light will be higher, and the small dimensions of the comb structure result in the effect to the user being substantially unaffected.

In the examples above, the operation of the two types of display is mutually exclusive. However, it is also possible to drive both pixels simultaneously. This will require different control of the pixel circuit, or else may require modification of the pixel circuit. For example, the EL elements may all be driven to a constant value to provide additional illumination for the first (LC or other) display element, thereby acting as a backlight as well as a colour filter. This may be under the control of the user to provide additional light when there is difficulty reading the screen. When using the EL display pixels as a backlight, the light passes only once through the top display element once, and the display drive signals may need to be modified to provide the intended image.

Other types of display device may also be used instead of reflective LC devices.

The first display element may comprise an electrophoretic display element in which the movement of absorbing particles in a transparent liquid is controlled based on electrostatic forces. In an electrochromic device the oxidation state of a chemical is controlled to provide variable transmittance. Display devices are also being developed based on electrowetting principles, in which surface tension forces are controlled to dictate the movement of liquids into or out of capillaries, again acting either to block or allow the passage of light. Phase change materials, for example metal hydrides, can also be used to form display devices.

Some of these types of display device will require polarisers and others will not. Although in the example above a polariser has been described, some forms of liquid crystal device also do not need polarisers, for example polymer dispersed liquid crystal (PDLC) and so-called “guest-host” type liquid crystals, in which LCD molecules rotate other optically active molecules.

The materials used in the EL display element and in the first display element have not been described in detail above, as the different possibilities are well known. Typically, the thickness of the organic electroluminescent material layer is between 100 nm and 200 nm. Typical examples of suitable organic EL materials which can be used are described in EP-A-0717446. Electroluminescent materials such as conjugated polymer materials as described in WO 96/36959 can also be used.

1. A display device comprising an array of display pixels, each pixel comprising a first display element which is drivable between at least two transmission states, the first display element overlying an electroluminescent display element.

2. A device as claimed in claim 1, wherein the electroluminescent display element comprises an organic material sandwiched between two electrodes and the organic material comprises an organic layer shared between all electroluminescent display elements.

3. A device as claimed in claim 2, wherein the layer is colour patterned so that different electrolumiescent display elements have different colours.

4. A device as claimed in claim 3, wherein the organic material provides colour filtering for the first display element.

5. A display device as claimed in any preceding claim, wherein the first display element comprises an electrophoretic, electrowetting, electrochromic or phase change material display element.

6. A display device as claimed in any one of claims 1 to 4, wherein the first display element comprises a liquid crystal.

7. A display device as claimed in claim 6, wherein the liquid crystal display element comprises an In Plane Switched (IPS) display element.

8. A display device as claimed in claim 7, wherein the IPS display element comprises a planar electrode structure having at least two interlocking electrodes, and wherein the electroluminescent display element comprises an organic material sandwiched between two electrodes, one of which comprises the planar electrode structure.

9. A device as claimed in claim 6, wherein the liquid crystal display element comprises liquid crystal material sandwiched between substantially transmissive first and second electrodes, and the electroluminescent display element comprises an organic material sandwiched between third and fourth electrodes, the second and third electrodes being at the junction of the liquid crystal display element and the electroluminescent display element.

10. A device as claimed in claim 9, wherein the first and second electrodes are formed from a substantially transparent conductor.

11. A device as claimed in claim 10, wherein the conductor comprises ITO.

12. A device as claimed in claim 9, 10 or 11, wherein a substantially transparent insulating layer is provided between the second and third electrodes.

13. A device as claimed in claim 9, 10, 11 or 12, wherein the third electrode is formed from ITO and the fourth electrode is a conducting opaque layer.

14. A device as claimed in claim 9, wherein a shared layer defines the second and third electrodes.

15. A device as claimed in any one of claims 9 to 14, wherein the fourth electrode is a reflective conducting layer and provides a reflective surface for a reflective display pixel.

16. A device as claimed in any preceding claim, wherein each pixel comprises a pixel drive circuit which operates in first and second modes, wherein in the first mode the first display element is driven in such a way that the first display element is rendered transparent and the electroluminescent display element is controlled, and in a second mode the electroluminescent display element is substantially non-emitting and the first display element is controlled.

17. A device as claimed in claim 16 in which the pixel drive circuit operates in a third mode in which both the first display element and the EL element are operated.

18. A device as claimed in any one of claims 9 to 15, wherein each pixel comprises a pixel drive circuit, comprising:
a first connection connecting the first electrode to a reference potential;
an address transistor for addressing the pixel, thereby allowing a data signal to pass to the remainder of the pixel;
a mode selection section of the circuit which in a first mode connects the second electrode to a fixed potential and couples an input signal to the fourth electrode, and which in a second mode couples an input signal to the second electrode and isolates the fourth electrode from the input signal.

19. A device as claimed in claim 18, wherein the mode selection section of the circuit in a third mode connects both electrodes simultaneously to a respective input signal.

20. A device as claimed in claim 18 or 19, wherein each pixel drive circuit further comprises a current source driven by the data signal, and wherein the mode selection section of the circuit comprises a first transistor coupled between the second electrode and a fixed potential, a second transistor coupled between the address transistor and the second electrode and a third transistor coupled between the current source and the fourth electrode, wherein in the first mode the first and third transistors are turned on and the second transistor is turned off, and in the second mode the first and third transistors are turned off and the second transistor is turned on.

21. A device as claimed in claim 20, wherein the current source comprises a fourth transistor, the gate of which is driven by the data signal.

22. A device as claimed in any one of claims 9 to 15, wherein each pixel comprises a pixel drive circuit, comprising:
a first connection connecting the first electrode to a reference voltage;
an address transistor for addressing the pixel, thereby allowing a data signal to pass to the remainder of the pixel;
a current source for converting the data signal to a current and applying the current to the second and third electrodes;
wherein for data signals in a first range, the current is used to address the electroluminescent element and for data signals in a second range a voltage is applied to the fourth terminal to turn off the electroluminescent element and the current is used to address the liquid crystal element.

23. A device as claimed in any one of claims 9 to 15, wherein each pixel comprises a pixel drive circuit, comprising:
a first connection connecting the first electrode to a reference voltage;
an address transistor for addressing the pixel, thereby allowing a data signal to pass to the remainder of the pixel;
a current source for converting the data signal to a current and applying the current to the second and third electrodes;
a storage capacitor connected between the first and second electrodes,
wherein for data signals in a first range, the current is used to address the electroluminescent element and for data signals in a second range a voltage is applied to the fourth electrode to turn off the electroluminescent element and the current is converted to a voltage by the storage capacitor and the voltage is used to address the liquid crystal element.
